(19) United States
(12) Patent Application Publication
(10) Pub. No.: US 2017/0019069 A1
(43) Pub. Date: Jan. 19, 2017

(54) High-Speed, High-Voltage GaN-Based Operational Amplifier

(71) Applicant: Eridan Communications, Inc., San Francisco, CA (US)

(72) Inventor: Marnie Dunsmore, San Francisco, CA (US)

(73) Assignee: Eridan Communications, Inc., San Francisco, CA (US)

(21) Appl. No.: 14/800,928

(22) Filed: Jul. 16, 2015

(51) Int. Cl. H03F 1/02; H03F 3/45; H03F 3/217; H03F 3/193; H03F 3/21

(52) U.S. Cl. CPC H03F 1/0211; H03F 3/193; H03F 3/211; H03F 3/2171; H03F 3/45179; H03F 2200/102; H03F 2200/451; H03F 2203/45051

(57) ABSTRACT

A high-speed, high-voltage gallium nitride based (GaN-based) operational amplifier (op amp) is disclosed. The combined high-speed, high-voltage capability allows the GaN-based op amp to serve as a dynamic power supply (DPS) for a radio frequency power amplifier (RFPA). When serving as a DPS for an RFPA, the GaN-based op amp is capable of supplying ampere-scale currents that accurately track rapidly-varying envelopes of non-constant envelope RF signals, thereby allowing the RFPA to convert high-bandwidth non-constant envelope RF signals to high RF output powers with high signal envelope accuracy.

### STATEMENT REGARDING FEDERALLY SPONSORED RESEARCH OR DEVELOPMENT

This invention was made with Government support under Contract No. FA8750-14-C-0099 awarded by the Air Force Research Laboratory on behalf of DARPA. The Government has certain rights in the invention.

### BACKGROUND OF THE INVENTION

Radio frequency (RF) transmitters are used to transmit RF signals over the air, space, or other transmission medium to a remote receiver. To compensate for attenuation of the RF signals as the RF signals propagate to the receiver, the RF signals are first amplified by a radio frequency power amplifier (RFPA), prior to being transmitted.

The principal function of an RFPA is to convert incoming low-power RF signals into high-power RF output signals. The RFPA accomplishes this by converting electrical energy supplied from a direct current (DC) power supply into RF power, in accordance with how the incoming low-power RF signal varies over time. To minimize energy loss, which is particularly important in battery-powered applications, it is desirable to maximize the efficiency of this conversion process. Unfortunately, maximizing efficiency is complicated by the fact that many modern wireless communications standards, for example, wideband code division multiple access (WCDMA), Worldwide Interoperability for Microwave Access (WiMAX), Long Term Evolution (LTE) and others, operate using non-constant envelope signals, often with high peak to average ratios, in which both the amplitude and angle (i.e., phase and/or frequency) of the signal varies over time. To avoid distorting the signal envelopes of these non-constant envelope signals in a linear RFPA, the RFPA must be backed off. However, because an RFPA typically operates at average output power or less most of the time (i.e., rarely operates at peak power), but is most efficient when operating at peak output power, power back off compromises the efficiency of the RFPA.

To increase the efficiency of an RFPA when non-constant envelope signals are involved, a dynamic power supply (DPS) 102 can be employed, as illustrated in FIG. 1. The DPS 102 produces a DPS voltage V_{SUPPLY}(t) which follows (i.e., “tracks”) the signal envelope Vₑₙᵥ of the non-constant envelope RF input signal RF_{IN}. Powering the RFPA 104 using the DPS voltage V_{SUPPLY}(t) prevents the RFPA 104 from dissipating large amounts of power when the magnitude of the non-constant envelope signal is small, thereby increasing the efficiency of the RFPA 104.

A DPS can also be employed in a polar modulator. In a polar modulator, the RFPA is operated as a switch, (i.e., is a switch-mode RFPA) and switched between compressed and cut-off states, rather than being biased in its linear region of operation as in a linear RFPA. In addition to the efficiency gained by operating the RFPA as a switch, it is possible to modulate the drain of a switch-mode RFPA (a technique known as “drain modulation”). This capability allows the signal envelope of a non-constant envelope signal to be separated and used to generate a DPS voltage V_{SUPPLY}(t), which is used to modulate the drain of the switch-mode RFPA. As the switch-mode RFPA converts the remaining constant-envelope RF signal to higher power, the switch-mode RFPA operates as an amplitude modulator, modulating the signal envelope contained in the DPS voltage V_{SUPPLY}(t) onto the constant-envelope RF signal, to produce the desired high-power non-constant envelope RF signal at the RFPA output.

Designing a DPS is difficult, whether the design is for an envelope tracking RFPA, switch-mode RFPA, or other envelope-following apparatus. RFPAs present themselves as a low-resistance load to a DPS yet must produce high RF output powers. In order for the RFPA to produce high RF output powers, the DPS must be capable of supplying large currents, and because of ohms law, V=I×R, the DPS must also be capable of generating very high voltages. The lower the DPS output load resistance is, the higher the DPS output current must be in order to drive a particular voltage at the DPS output. Conventional DPSs employ silicon-based (Si-based) op amps made from Si-based metal-oxide-semiconductor field effect transistors (MOSFETs). Unfortunately, because Si-based MOSFETs have low breakdown voltages, Si-based MOSFET op amps are unsuitable for DPS applications in which very high currents and very high voltages must be simultaneously supplied to an RFPA designed to produce very large RF output powers. Moreover, Si-based MOSFET op amps have limited bandwidth capability, particularly when they are operating at high currents and high voltages. This bandwidth constraint prevents Si-based MOSFET op amps from being used in situations where the bandwidth of the signal envelope of a non-constant envelope signal is high. The present invention addresses and provides solutions to these problems.

### BRIEF SUMMARY OF THE INVENTION

A gallium nitride based (GaN-based) operational amplifier (op amp) is disclosed. The GaN-base op amp is capable of operating at high voltages and is simultaneously capable of driving ampere-scale currents, even to very low-resistance loads. The GaN-based op amp is further capable of operating at high frequencies while supplying ampere-scale currents. In one embodiment of the invention, the GaN-based op amp is configured to serve as a dynamic power supply (DPS) for a radio frequency power amplifier (RFPA). When serving as a DPS for an RFPA, the GaN-based op amp is capable of supplying ampere-scale currents that accurately track rapidly-varying envelopes of non-constant envelope RF signals, thereby allowing the RFPA to convert high-bandwidth non-constant envelope RF signals to high RF output powers with high signal envelope accuracy.

Further features and advantages of the invention, including a detailed description of the above-summarized and other exemplary embodiments of the invention, will now be described in detail with respect to the accompanying drawings, in which like reference numbers are used to indicate identical or functionally similar elements.

### BRIEF DESCRIPTION OF THE DRAWINGS

FIG. 1 is a drawing illustrating how a prior art dynamic power supply can be employed to improve the efficiency of a radio frequency power amplifier;

FIG. 2 is a schematic drawing of a high-voltage, high-speed operational amplifier (op amp), according to an embodiment of the present invention;

FIG. 3 is a drawing illustrating the direct current (DC) level-shifting performed by the first level-shifter stage of the op amp in FIG. 2;

FIG. 4 is a schematic drawing of an alternative level-shifter stage that can be used for the first and second level-shifter stages of the op amp depicted in FIG. 2;

FIG. 5 is a schematic drawing of the small signal equivalent half circuits of the first differential gain stage of the op amp depicted in FIG. 2;

FIG. 6 is a schematic drawing of a self-regulating current source which can be used to implement the tail current sources of the first and second differential gain stages of the op amp depicted in FIG. 2;

FIG. 7 is a simplified drawing of the I_{DS} versus V_{DS} characteristic curves of the GaN-HEMTs of the first differential gain stage of the op amp depicted in FIG. 2;

FIG. 8 is a simplified drawing of the transconductance gₘ versus gate-source voltage V_{gs} of the GaN-HEMTS of the first differential gain stage of the op amp depicted in FIG. 2, highlighting the transconductance compression phenomenon that can be exhibited by the GaN-HEMTS;

FIGS. 9A and 9B are Bode plot diagrams showing the open-loop frequency response of a simulated op amp having the same general design as the op amp depicted in FIG. 2;

FIG. 10 is a drawing showing how the op amp depicted in FIG. 2 was configured to evaluate the power supply rejection (PSR) performance of the output stage of the op amp;

FIG. 11 is a plot showing the closed-loop, time-domain response and PSR performance of the output stage of the op amp depicted in FIG. 2 when the op amp was configured as in FIG. 10 and stimulated by a ten-volt step stimulus;

FIG. 12 is a plot showing the PSR performance of the output stage of the op amp depicted in FIG. 2 as a function of frequency, when the op amp was configured as shown in FIG. 10;

FIG. 13 is a drawing illustrating how the op amp depicted in FIG. 2 can be configured to serve as a dynamic power supply (DPS) for a switch-mode power amplifier (SMPA) of a polar modulator, in accordance with one embodiment of the invention;

FIGS. 14 and 15 show the large signal transient response of the op amp depicted in FIG. 2 when the op amp was configured to drive a very low resistance (30 Ω) load; and

FIG. 16 is a drawing illustrating how the op amp depicted in FIG. 2 can be configured to serve as a DPS for an envelope tracking (ET) amplifier that employs a linear power amplifier, in accordance with one embodiment of the invention.

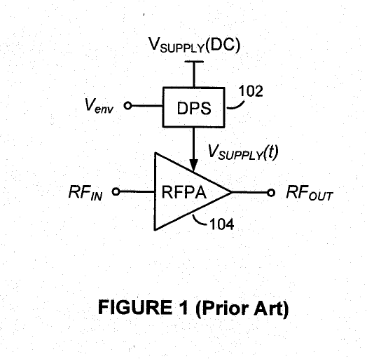

### DETAILED DESCRIPTION

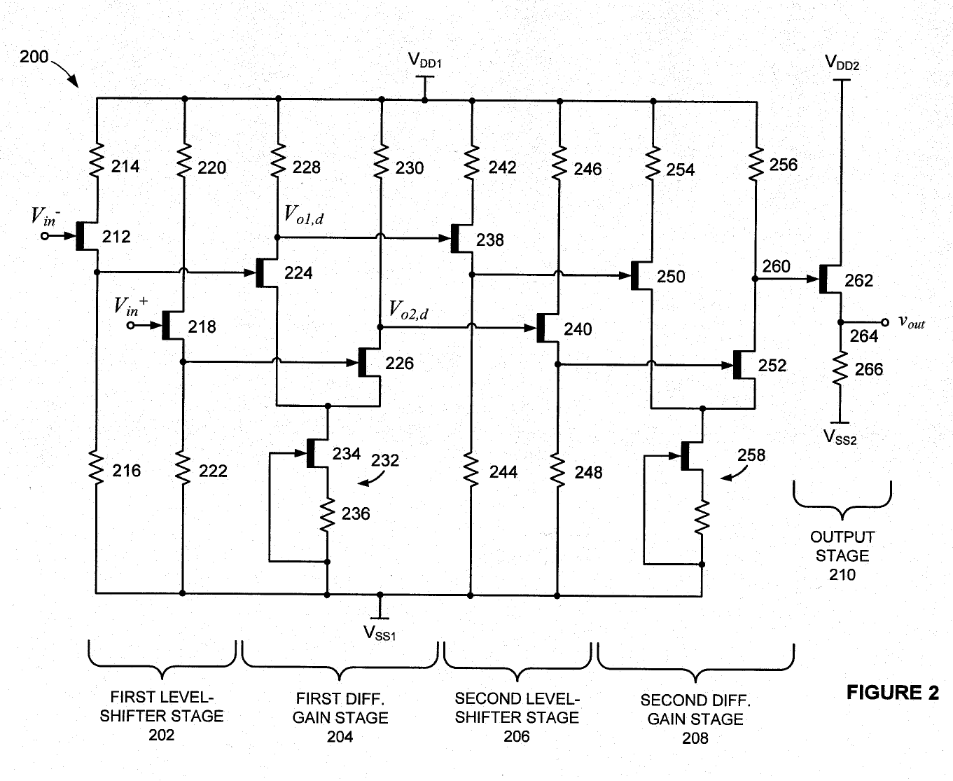

Referring to FIG. 2, there is shown an operational amplifier (op amp) 200, according to an embodiment of the present invention. The op amp 200 comprises a first level-shifter stage 202, a first differential gain stage 204, a second level-shifter stage 206, a second differential gain stage 208, and an output stage 210. The op amp 200 is fabricated in a single integrated circuit (IC) with all of the transistors of the various stages of the op amp 200 being depletion mode field-effect transistors (FETs). In a preferred embodiment of the invention, all of the depletion mode FETs comprise aluminum gallium nitride/gallium nitride (AlGaN/GaN) high electron mobility transistors (GaN-HEMTs). GaN-HEMTs have very high breakdown voltages (hundreds of volts), which allows the op amp 200 to operate at high drain voltages. GaN-HEMTs also have high drift velocities (approaching 3×10⁷ cm/s) and high current-gain cut-off frequencies f_{T} (exceeding 70 GHz). As will be discussed in detail below, in one embodiment of the invention the high-speed, high-voltage op amp 200 is employed to serve as a dynamic power supply (DPS) for a radio frequency power amplifier (RFPA). The combined high breakdown voltage property and high-speed capability of the GaN-HEMTs allow the DPS to be capable of supplying and dynamically varying ampere-scale currents over a wide range of frequencies—from 0 Hz up to tens of MHz. Consistent with the preferred embodiment of implementing the various depletion mode FETs of the op amp 200 using GaN-HEMTs, in the description that follows the depletion mode FETs making up the op amp 200 will be referred to as GaN-HEMTs. It should be emphasized, however, that the op amp 200 need not necessarily be implemented using GaN-HEMTs. In other words, depending on the application (for example, perhaps depending on speed and power requirements), other types of depletion mode devices can be possibly used.

As illustrated in FIG. 2, the first level-shifter stage 202 comprises a GaN-HEMT 212 with associated bias resistors 214 and 216 and a GaN-HEMT 218 with associated bias resistors 220 and 222. The GaN-HEMTs 212 and 218 are substantially identical, having the same gate width (W) to length (L) ratio W/L, i.e., W(212)/L(212)=W(218)/L(218). Additionally, R(214)=R(220) and R(216)=R(222). The first level-shifter stage 202 does not need to produce any voltage gain. Accordingly, the gate widths W(212) and W(218) of the GaN-HEMTs 212 and 218 can be made to be small, for example, significantly smaller than the gate widths W(224) and W(226) of the GaN-HEMTs 224 and 226 of the first differential gain stage 204, which is designed to produce a large differential voltage gain A_{d1}. In one embodiment of the op amp 200, the GaN-HEMTs 212 and 218 are designed to have gate widths W(212)=W(218) of 25 μm.

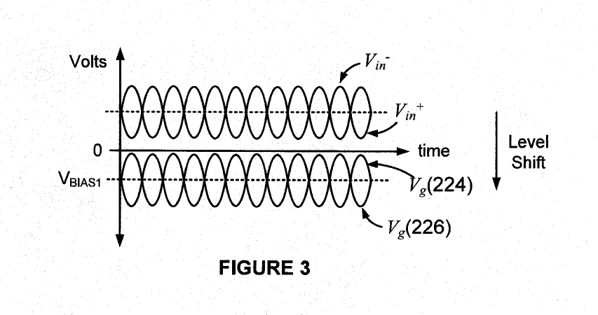

The first level-shifter stage 202 serves a dual purpose. First, it shifts the DC components of the input voltages Vᵢₙ⁻ and Vᵢₙ⁺ to a suitable DC bias voltage V_{BIAS1} for the inputs to the GaN-HEMTs 224 and 226 making up the succeeding first differential gain stage 204. Second, it serves to follow the AC components of the input voltages, vᵢₙ⁻ and vᵢₙ⁺, to the differential input (gates of the GaN-HEMTs 224 and 226) of the first differential gain stage 204. GaN-HEMTs are depletion mode devices and consequently have negative threshold voltages. Level-shifting the DC components of the input voltages Vᵢₙ⁻ and Vᵢₙ⁺ thus involves shifting the DC component of each input voltage Vᵢₙ⁻ and Vᵢₙ⁺ to a more negative DC value V_{BIAS1}, as illustrated in FIG. 3. Since the GaN-HEMTs 212 and 218 are substantially identical (i.e., are “matched”) and R(214)=R(220) and R(216)=R(222), each source follower produces an identical gate voltage for each half-circuit of the first differential gain stage 204. The value of the gate voltage at the input of the first differential gain stage 204 determines the DC operating point Q₁ of the first differential gain stage 204. To a first approximation, this DC operating point Q₁ is established ratiometrically by the resistance values of the bias resistors 214, 216, 220 and 222. Ignoring the effect of varying V_{ds}(212) and V_{ds}(218) in GaN-HEMTs 212 and 218, which is small compared to the voltage dropped across the bias resistors 214, 216, 220 and 222, the ratiometric setup of R(214)/R(216) and R(220)/R216) yields bias voltages at the gates of the first differential gain stage 204 according to the following relationships: [R(214)/R(216)*(V_{DD1}−V_{SS1})]+V_{SS1}−V_{gs}(212) and [R(220)/R(222)*(V_{DD1}−V_{SS1})]+V_{SS1}−V_{g},(218).

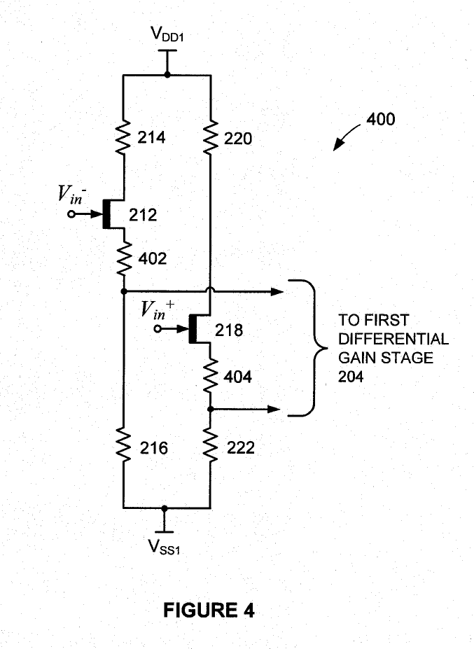

It should be mentioned that there are other level-shifting approaches that could be alternatively used to level-shift the input voltages Vᵢₙ and For example, a source follower/resistor level-shifter stage or a source follower/Schottky diode level-shifter stage could be used. FIG. 4 illustrates, for example, how a source follower/resistor level-shifter stage 400 could be used. The source follower/resistor level-shifter 400 is similar in construction to the first level-shifter stage 202 described above in reference to FIG. 2, but further includes source resistors 402 and 404, which, depending on their resistance values and the bias currents of the GaN-HEMTs 212 and 218, provide additional voltage level shifts beyond the level shifts provided by the level-shifter stages 202 and 204. The source follower/Schottky diode level-shifter stage would be similarly constructed, but using one or more series-connected Schottky diodes substituting for each of the source resistors 402 and 404 and possibly one or more self-regulating current source(s) substituting for the resistors 216 and 222. While these or any other type of level-shifter could be employed, in the preferred embodiment of the invention both the first and second level-shifter stages 202 and 206 are implemented as shown and described above in reference to FIG. 2, i.e., as ratiometric-biasing level shifter stages 202 and 206.

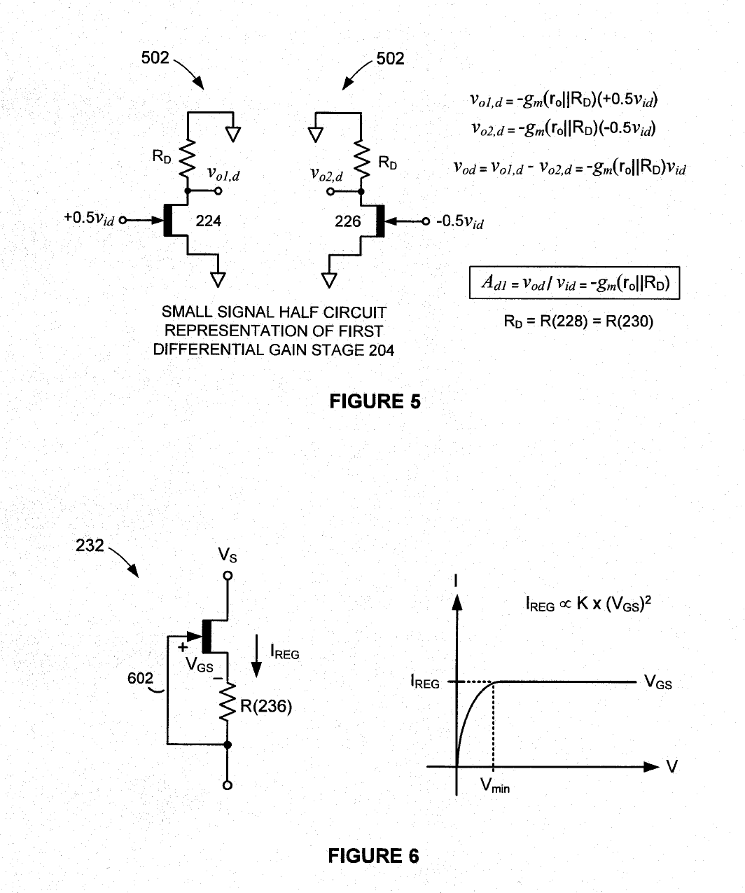

The first differential gain stage 204 comprises GaN-HEMTs 224 and 226, first and second drain resistors 228 and 230, and a tail current source 232. The purpose of the first differential gain stage 204 is to amplify the input differential voltage v_{id}=(vᵢₙ⁻−vᵢₙ⁺) sourced to it from the first level-shifter stage 202 and produce a differential output voltage v_{od}=v_{o1,d}−v_{o2,d} that is a voltage-amplified version of the received input differential voltage v_{id}=(vᵢₙ⁻−vᵢₙ⁺). FIG. 5 is a schematic drawing of the small signal equivalent half circuits 502 of the first differential gain stage 204. Each half circuit 502 is a common source amplifier. The differential voltage gain A_{d1} can therefore be determined to be: A_{d1}=v_{od}/v_{id}=−gₘ(rₒ∥R_{D}), where rₒ is the small signal output resistance of each half circuit, R_{D}=R(228)=R(230), and gₘ is the transconductance of the GaN-HEMTs 224 and 226. Since the GaN-HEMTs 224 and 226 are configured to operate in their saturation regions:

gₘ=μC_{gs}(224)*([W(224)/L(224)]*(V_{gs}(224)−Vₜₕ(224))=μC_{gs}(226)*[W(226)/L(226)]*(V_{gs}(226)=Vₜₕ(226)),

where μ is the electron mobility of the GaN-HEMTs 224 and 226), C_{gs} is the gate-source capacitance of the GaN-HEMTs 224 and 226, W(224)/L(224)=W(226)/L(226) is the gate width to gate length ratio of the GaN-HEMTs 224 and 226, and Vₜₕ(224)=Vₜₕ(226) is the threshold voltage of the GaN-HEMTs 224 and 226. In one embodiment of the invention, the first differential gain stage 204 is optimized for high differential voltage gain A_{d1}. According to that embodiment of the invention, the gate widths W(224) and W(226) of the GaN-HEMTs 224 and 226 are therefore made to be large (for example significantly larger than the gate widths W(212) and W(218) of the GaN-HEMTs 212 and 218 in the first level-shifter stage 202), and the drain resistances R_{D}=R(228)=R(230) are made high, for example, using high-resistivity, bulk GaN resistors. Bulk GaN resistors have a low manufacturing variance (less than 10%) and therefore allow highly-matched passive loads to be designed and the differential gain stages 204 and 208 to be designed for high linearity. Bulk GaN resistors can also be used to make the other resistors in the op amp 200, for example, the bias resistors 214-222 and 242-248 of the first and second level-shifter stages 202 and 206 and the current-setting resistors 236 and 258 of the self-regulating current sources 232 and 258 in the first and second differential gain stages 204 and 208. Thin-film resistors (e.g., thin-film nichrome resistors) may also or alternatively be used for some or all of the resistors in the op amp 200. However, since bulk GaN resistors offer a much larger resistance per square compared to thin-film resistors, and because various of the resistors in the op amp 200 are designed to have high resistance values (for example, the drain resistors 228, 230, 254 and 256 of the first and second differential gain stages 204 and 208), it is preferred to use bulk GaN resistors, since by using them the overall size of the IC in which the op amp 200 is fabricated can be minimized.

The tail current source 232 of the first differential gain stage 204 can be implemented in various ways. In one embodiment of the invention it is implemented using a self-regulating current source 232 that comprises a GaN-HEMT 234 and a current-setting resistor 236 connected between the source and gate of the GaN-HEMT 234. As illustrated in FIG. 6, the self-regulating current source 232 produces a constant, regulated current I_{REG}, which is approximately proportional to K*V_{GS}²(234), where K is a constant having a value that depends on the material and electronic properties of the GaN-HEMT 234 and the width-to-length ratio W(234) of the GaN-HEMT 234. Since the magnitude of the regulated current I_{REG} depends on the gate-source V_{GS}(234) voltage applied across the gate-source terminals of the GaN-HEMT 234, it can be set based on the selected resistance value of the current-setting resistor 236. Due to the presence of the feedback path 602: V_{GS}(234)=−I_{REG}×R(236). In other words, the fed-back voltage results in a negative voltage being applied across the gate-source terminals of the GaN-HEMT 234. Any propensity of the current through the self-regulating current source 232 to deviate from I_{REG} is opposed by the negative feedback. For example, if the voltage V_{S} was to be increased in an attempt to increase the drain current through the GaN-HEMT 234, the voltage drop across the current-setting resistor 236 would increase, but since the fed-back voltage is negatively applied across the gate-source terminals of the GaN-HEMT 234, the GaN-HEMT 234 would oppose the increase in current and force the current back down to I_{REG}. The current source 232 is therefore “self-regulating.” So long as the voltage V_{S} is maintained above a minimum voltage Vₘᵢₙ (which it is when configured in the differential gain stage 204), the self-regulating current source 232 remains effective at regulating the constant current I_{REG}, despite any variation in the voltage V_{S}. It should be mentioned that since the current I_{REG} also depends on the gate width W(234) of the GaN-HEMT 234, the self-regulating current source could be designed without the current-setting resistor 236, i.e., by connecting the source of the GaN-HEMT 234 directly to its source. Setting the required tail current I_{REG} would then be accomplished during layout with appropriate selection of the gate width W(234) of the GaN-HEMT 234.

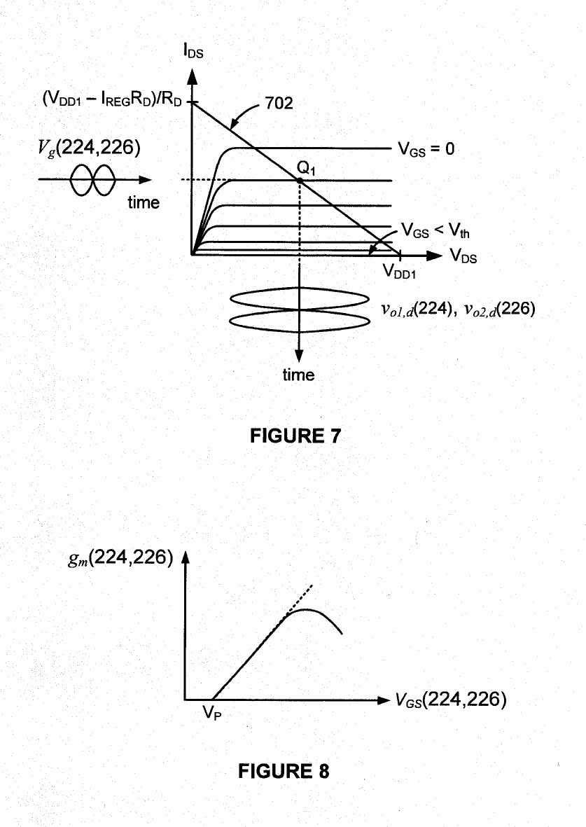

FIG. 7 is a simplified drawing of the I_{DS} versus Vᵢₛ characteristic curves of the GaN-HEMTs 224 and 226 of the first differential gain stage 204. (Note that the characteristic curves are not actual characteristic curves and are not drawn to scale. They are provided to simply highlight the operation of the first differential gain stage 204 and describe how the DC operating point Q₁ of the first differential gain stage 204 may be set.) Also shown below the characteristic curves are the small signal amplified drain voltages v_{o1,d} and v_{o2,d} produced at the drains of the GaN-HEMTs 224 and 226 of the first differential gain stage 204. The two voltages v_{o1,d} and v_{o2,d} are 180 out of phase and each signal swings about the DC operating point Q₁ with a drain-source voltage determined by the load line 702. Since the DC level shift introduced by the first level-shifter stage 202 is what determines the DC operating point Q₁ of the first differential gain stage 204, it is desirable to select the resistance ratio R(214)/R(216)=R(220)/R(222) so that the DC operating point Q₁ is centered in the region of the characteristic curves where the transconductance gₘ is high. To avoid distortion, it is further desirable for the voltages v_{o1,a} and v_{o2,d} to swing entirely within the saturation regions of operation of the GaN-HEMTs 224 and 226, i.e., not into the ohmic (resistive) or subthreshold regions of the GaN-HEMTs 224 and 226. Establishing the appropriate DC operating point Q₁ thus also takes into consideration the differential gain A_{d1} for which the first differential gain stage 204 is designed.

It should be mentioned that GaN-HEMTs can exhibit a phenomenon known as transconductance compression, where at higher values of V_{gs} the transconductance gₘ compresses, as illustrated in FIG. 8. The onset of compression and the maximum value of the transconductance gₘ that can be achieved can also depend on the drain-source voltage V_{ds} of the GaN-HEMTs 224 and 226. This transconductance compression phenomenon, including its dependency on the drain-source voltage V_{ds}, can also be taken into consideration, if necessary or desired, in optimizing the DC operating point Q₁ and differential voltage gain A_{d1} of the first differential gain stage 204.

In addition to the first level-shifter stage 202 and first differential gain stage 204, the op amp 200 further comprises a second level-shifter stage 206 and a second differential gain stage 208 (see FIG. 2). Similar to the first level-shifter stage 202, the second level-shifter stage 202 comprises GaN HEMTs 238 and 240 and associated bias resistors 242, 244, 246 and 248, and similar to the first level-shifter stage 202, the second level-shifter stage 206 serves a dual purpose. First, it shifts the DC component of the amplified differential output signal V_{o1,d}−V_{o2,d} produced by the first differential gain stage 204 to a DC level V_{BIAS2} that is compatible with the negative threshold voltages of the GaN-HEMTs 250 and 252 of the subsequent second differential gain stage 208 and establishes a suitable DC operating point Q₂ in the I_{DS} versus V_{DS} characteristic curves of the GaN-HEMTs 250 and 252 of the second differential gain stage 208. Second, the second level-shifter stage 206 serves to follow the output voltages, v_{o1,d} and v_{o2,d}, produced by the first differential gain stage 204 to the differential input of the second differential gain stage 208 (i.e., to the gates of GaN-HEMTs 250 and 252). The GaN-HEMTs 238 and 240 of the second level-shifter stage 206 are matched, having the same gate width (W) to length (L) ratio W/L, i.e., W(238)/L(238)=W(240)/L(240). Additionally, R(242)=R(246) and R(244)=R(248). Establishing the DC bias voltage V_{BIAS2} and DC operating point Q₂ for the second differential stage 208 is performed using the same ratiometric biasing approach used to establish the DC bias voltage V_{BIAS1} and DC operating point Q₁ of the first differential stage 204, in other words, by selecting the appropriate ratio R(242)/R(244)=R(246)/R(248).

The second differential gain stage 208 comprises, in addition to the GaN-HEMTs 250 and 252, drain resistors 254 and 256 and a constant current source 258, which, similar to the constant current source 232 of the first differential gain stage 204 can be implemented using a second self-regulating current source (see FIG. 6 above). From a small signal perspective, the second differential gain stage 208 is directly coupled to the first differential gain stage 202, where the term “directly coupled” means that no AC coupling capacitors are incorporated into the op amp design to couple the small signal differential voltage v_{o1,d}−v_{o2,d} produced by the first differential gain stage 204 to the differential input (gates of GaN-HEMTs 250 and 252) of the second differential gain stage 208. The second differential gain stage 208 serves to further amplify the amplified the differential voltage v_{o1,d}−v_{o2,d}, thereby increasing the overall differential voltage gain of the op amp 200 to: A_{d}=A_{d1}*A_{d2}. In one embodiment of the invention, the op amp 200 is designed to achieve the maximum differential voltage gain A_{d} realizable without causing unacceptable distortion. According to that embodiment of the invention, the differential voltage gain A_{d1} of the first differential gain stage 204 and the differential voltage gain A_{d2} of the second differential gain stage 208 are therefore both optimized for maximum realizable differential voltage gain. Optimizing the differential voltage gain A_{d2} of the second differential gain stage 208 can be performed in a manner similar to the procedure described above in optimizing the differential voltage gain A_{d1} of the first differential gain stage 204. In one embodiment of the invention, the widths W(224)=W(226) of the GaN-HEMTs 224 and 226 of the first differential gain stage 204 are sized to be about half the widths W(238)=W(240) of the GaN-HEMTs 238 and 240 of the second differential gain stage 208. This has the effect of proportioning the gate-source capacitances C_{gs}(224)=C_{gs}(226) of the GaN-HEMTs 224 and 226 of the first differential gain stage 204 to be about one half of the capacitances C_{gs}(238)=C_{gs}(240) of the GaN-HEMTs 238 and 240 of the second differential gain stage 208, which is desirable if the goal is to place the dominant poles of the op amp 200, which are a function of C_{gs}, at the output of the second differential gain stage 208 of the op amp 200. This approach of optimizing both the first differential gain stage 204 and the second differential gain stage 208 is made possible due to the inherently low noise of GaN-HEMTs, and is dissimilar to the approach taken in designing silicon-based op amps, where minimizing noise in the first stage is usually the higher design priority.

The second differential gain stage 208 has a single-ended output 260, which is directly coupled, again without using an AC coupling capacitor, to the input of the output stage 210. The output stage 210 comprises a GaN-HEMT 262 configured as a source follower having very high current gain. Its principal function is to supply very large currents to a load 266, which as shown in FIG. 2 can be directly coupled to the output 264 of the op amp 200. (Note that the load 266 will not normally be an actual component of the op amp 200. However, it is possible to manufacture the load 266 on the same IC as the op amp 200.) In some applications, the load resistance can be very low (e.g., 505)). Exploiting the high-power capability of the GaN-HEMT 262 and its extremely high breakdown voltage (which can be hundreds of volts), the op amp 200 is fully capable of generating the very high voltages necessary to generate ampere-scale currents, even for a very low-resistance load. Moreover, since the GaN-HEMT 262 has a high drift velocity (approaching 3×10⁷ cm/s) and an extremely high maximum current-gain cut-off frequency f_{T} (exceeding 70 GHz), the output stage 210 is capable of supplying ampere-scale currents while the op amp 200 is operating at very high closed-loop operating frequencies (for example, tens of MHz and higher).

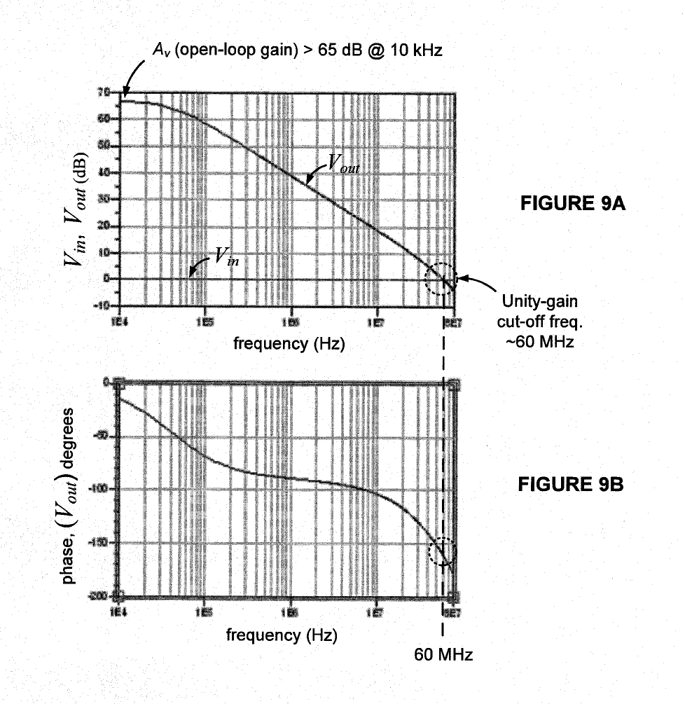

As discussed in further detail below, the combined high-power, high-speed capability of the op amp 200 makes the op amp 200 well-suited for serving as a high speed, high-current dynamic power supply (DPS) in a polar modulator, envelope tracking amplifier, or other envelope following apparatus. FIGS. 9A and 9B show the open-loop frequency response (Bode plots) of a simulated op amp having the same general design as the op amp 200 depicted in FIG. 2. In the simulation, the first and second drain supply voltages V_{DD1} and V_{DD2} applied to the op amp 200 were both set to 30 V, and the first and second source supply voltages Vₛₛ₁ and Vₛₛ₂ were set to −10 V and 0 V. The Bode plots reveal that the simulated op amp has an open loop gain Aᵥ=Vₒᵤₜ/Vᵢₙ that exceeds 60 dB (i.e., greater than 1000) at 10 kHz, and has a unity gain crossover frequency of ˜60 MHz and a phase margin of approximately 15 degrees.

It should be emphasized that the simulation results provided in FIGS. 9A-9B, as well as the simulation results provided in FIGS. 11, 12, 14 and 15, are provided only to demonstrate the operational capability of an op amp having the same general design as the op amp 200 depicted in FIG. 2. Whereas the simulation results highlight some of the performance capabilities of the op amp 200, the highlighted performance capabilities should not be construed as being performance limitations of the op amp 200. Therefore, the simulation methods and results should not be used to restrict the scope of the invention in any way, unless specifically reflected in the words of the appended claims.

When the op amp 200 is used to supply power to the load 266, it is desired (or required in some cases) for the power supply of the output stage 210 of the op amp 200 to be as noise-free as possible. This is particularly true when the load of the op amp 200 (represented by the resistor 266 in FIG. 2) is an RFPA, since any noise that appears at the output 264 of the op amp 200 becomes an undesired sideband in the frequency response of the RFPA. Since the output stage 210 is a source follower, serving as a current source, for a given load current a minimum voltage V_{ds}(262) (i.e., minimum headroom voltage) should be maintained across the drain-source terminals of the GaN-HEMT 262 of the output stage 210 at all times (in order to maintain the GaN-HEMT 262 in its saturation region of operation and thus permit optimal power supply rejection (PSR)). In the source follower configuration, PSR is proportional to l/gₘ*rₒ, where gₘ is the transconductance of the GaN-HEMT 262 of the output stage 210 and rₒ is the output resistance of the output stage 210. To avoid unnecessary power dissipation in the output stage 210, while maintaining optimal PSR, it is desirable for the headroom voltage to be just sufficient to bias the GaN-HEMT 262 into saturation, keeping a voltage drop V_{ds,sat}(262) across the GaN-HEMT 262, but no larger. Additionally, in an effort to make power delivery to the output stage 210 as noise-free as possible, in one embodiment of the invention the output stage 210 is configured so that it is powered by a second (i.e., separate and isolated) DC drain power supply V_{DD2}, while the remaining prior stages of the op amp 200 (i.e., the first level-shifter stage 202, first differential gain stage 204, second level-shifter stage 206, and second differential gain stage 208) are configured to be powered by the first drain power supply V_{DD1}. This embodiment of the invention is the same as in the exemplary embodiment of the op amp 200 described above and depicted in FIG. 2. Separating the output stage 210 power supply V_{DD2} from the prior stage power supply V_{DD1} increases the noise isolation of the output stage 210. The separation also provides the benefit of not disrupting the DC biasing of the prior stages. It should be noted that power supply noise may not be a concern in some applications of the op amp 200, in which case the op amp 200 can be alternatively configured so that all stages of the op amp 200 share the same DC power supply.

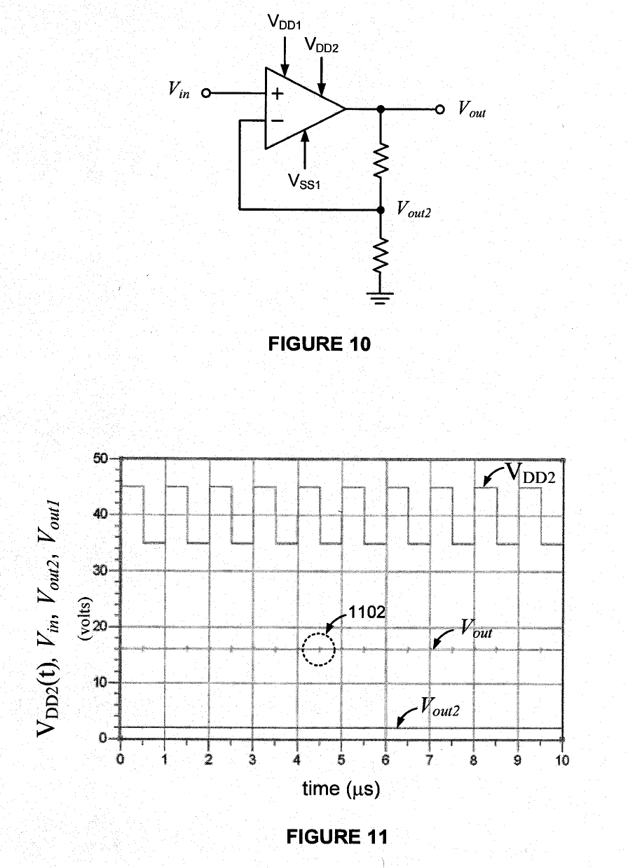

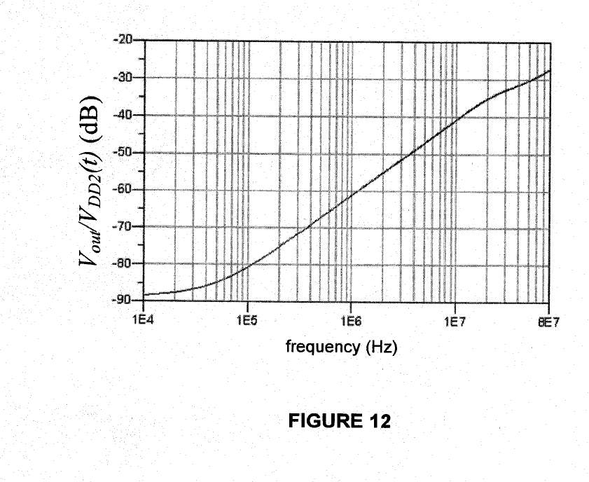

Low noise performance is also realized by virtue of using a GaN-HEMT (GaN-HEMT 262) in the output stage 210. In a simulation in which a 1 MHz ten-volt step square wave (representative of a “very noisy” drain power supply V_{DD2}) was applied to the V_{DD2} power supply port of the op amp 200 and the op amp 200 was configured in a closed-loop configuration (as illustrated in FIG. 10), the output voltage Vₒᵤₜ of the op amp 200 was seen to be barely affected by the noise present on the V_{DD2} power supply. FIG. 11 is a voltage versus time plot showing the results of this simulation. All that can be observed in the op amp output voltage Vₒᵤₜ are the small and insignificant “ticks” 1102 that are aligned with the edge transitions of the square wave. The relative flatness of the output voltage Vₒᵤₜ that is observed is partly due to the output stage power supply V_{DD2} being separated from the prior-stage power supply V_{DD1} and the feedback loop, which works to suppress the noise. As alluded to above, the noise suppression capability of the output stage 210 can be quantified in a figure of merit known as PSR, where PSR=Vₒᵤₜ/V_{DD2}. FIG. 12 shows the simulated PSR performance of the output stage 210 of the op amp 200. The simulation results show that the PSR of the output stage 210 is very high, remaining greater than 40 dB up to frequencies of 10 MHz, for example.

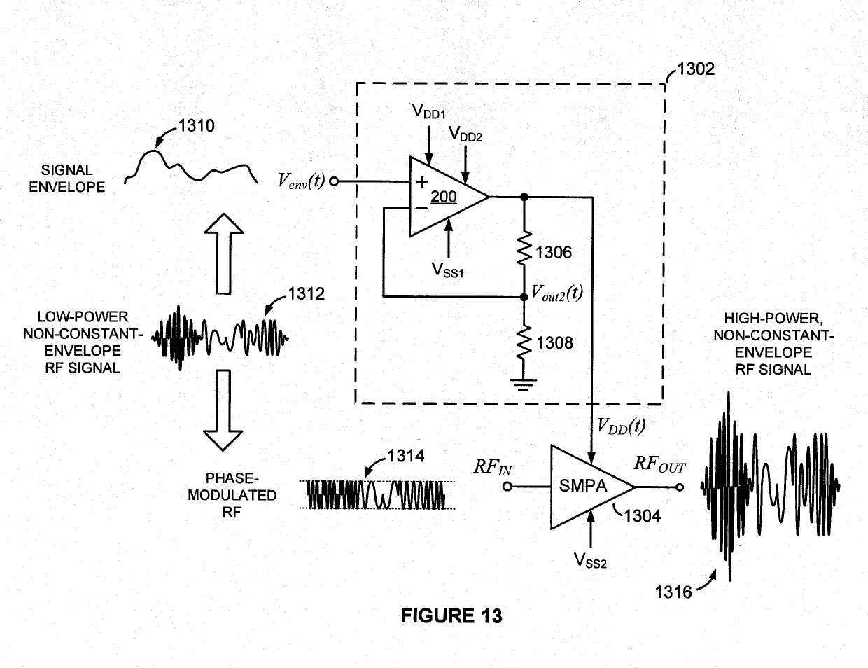

The op amp 200 can be used in a wide variety of applications. Its high-power, high-speed capability makes it particularly attractive for use in serving as a DPS in a polar modulator or an envelope tracking (ET) amplifier. Since the op amp 200 is capable of supplying ampere-scale currents to an RFPA that produces tens of watts of RF output power, even for non-constant envelope signals having bandwidths in excess of 10 MHz, the op amp 200 is well-suited for serving as a DPS in such applications. FIG. 13 is a drawing illustrating how the op amp 200 can be configured to serve as a DPS 1302 for a switch-mode PA (SMPA) 1304 of a polar modulator, in accordance with one embodiment of the invention. The DPS 1302 comprises the op amp 200 and first and second resistors 1306 and 1308, which serve as a voltage divider and are used to feed back a regulating voltage Vₒᵤₜ₂(t) to the inverting input of the op amp 200. (Note that in one embodiment of the invention, the SMPA 1304, like the op amp 200, is designed using one or more GaN-HEMTs. According to that embodiment of the invention, the GaN-based SMPA 1304 and op amp 200 can be, though not necessarily, fabricated in a single GaN-based IC.) The signal envelope 1310 of the low-power non-constant envelope input RF signal 1312 can be formed in various ways. For example, it can be formed by extracting it from the incoming non-constant envelope input RF signal 1312 using an envelope detector. Or, as another example, it can be produced at baseband using digital processing techniques, for example, using a digital signal processor (DSP) programmed to execute a coordinate rotation digital computer (CORDIC) algorithm. The op amp 200 is configured to generate a DPS voltage V_{DD}(t) that varies over time according to the amplitude variations in the envelope voltage Vₑₙᵥ(t) applied to the noninverting input of the op amp 200. The phase-modulated RF component 1314 of the non-constant envelope signal 1312 has a constant (i.e., non-time-varying) envelope. It is applied to the RF input port RF_{IN} of the switch-mode PA (SMPA) 1304 while the DPS voltage V_{DD}(t) produced by the op amp 200 is applied to the power supply port (drain) of the SMPA 1304. Accordingly, as the SMPA 1304 converts the phase-modulated RF 1314 to higher power, the DPS voltage V_{DD}(t) modulates the drain of the SMPA 1304, causing the SMPA 1302 to impress the signal envelope 1310 back onto the constant-envelope RF signal and produce the desired high-power, non-constant envelope RF output signal 1316 at its RF output RF_{OUT}.

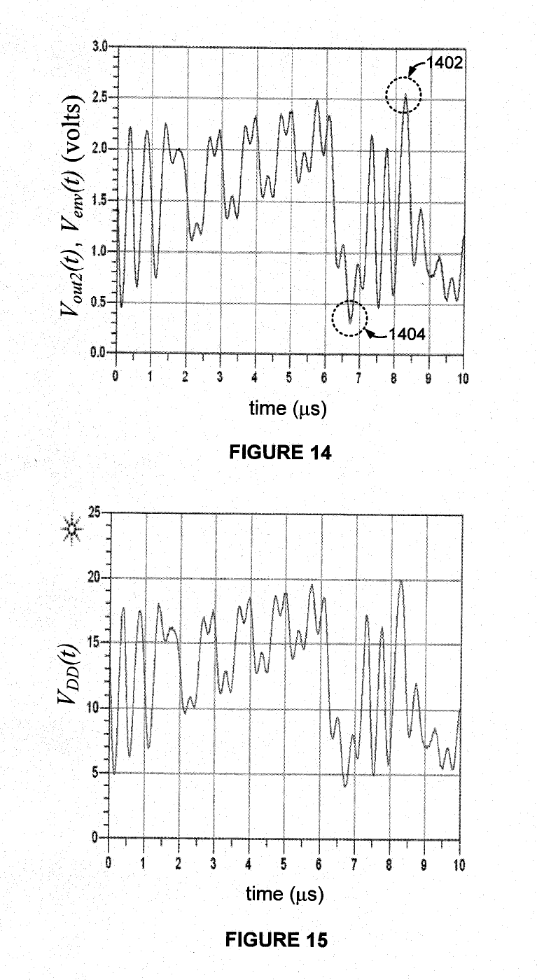

FIGS. 14 and 15 show the large signal transient response of the op amp 200 when serving as a DPS for an SMPA (similar to as in FIG. 13). The simulation was performed with the first and second drain supply voltages V_{DD1} and V_{DD2} to the op amp 200 both set to 30 V, the first and second source supply voltages V_{SS1} and V_{SS2} set to −10 V and 0 V, and for a worst-case load resistance of 30 Ω in a parallel with a 200 pF capacitor. The simulation results in FIG. 14 reveal that when the op amp 200 is configured as a DPS, the fed back regulating voltage Vₒᵤₜ₂(t) matches the input envelope voltage Vₑₙᵥ(t) nearly entirely. There are only a few nearly-imperceptible deviations that occur in this worst-case simulated condition of driving a very low resistance (30 Ω) load, two of which are indicated by the circles with reference numbers 1402 and 1404. The near complete alignment of the fed back regulating voltage Vₒᵤₜ₂(t) and input envelope voltage Vₑₙᵥ(t) provides an indication that the op amp 200 operates with very high accuracy. The simulation results in FIG. 15 show that: (1) the dynamic power supply voltage V_{DD}(t) accurately tracks the input envelope voltage Vₑₙᵥ(t); (2) that V_{DD}(t) has a slew rate of greater than 20V/μs; (3) that the op amp 200 produces a closed-loop voltage gain Av=V_{DD}(t)/Vₑₙᵥ(t) of approximately seven; and (4) the op amp produces an output voltage swing between a low voltage of less than 5 V and a peak voltage of 20 V. These simulation results validate the effectiveness of the op amp 200 at serving as a DPS for an SMPA, and in particular, its ability to supply ampere-scale currents when driving a very low input resistance SMPA that produces tens of watts of RF output power. The simulation results also validate the effectiveness of the op amp 200 at accurately tracking fast-changing signal envelopes, even when ampere-scale currents are being generated and supplied to the SMPA.

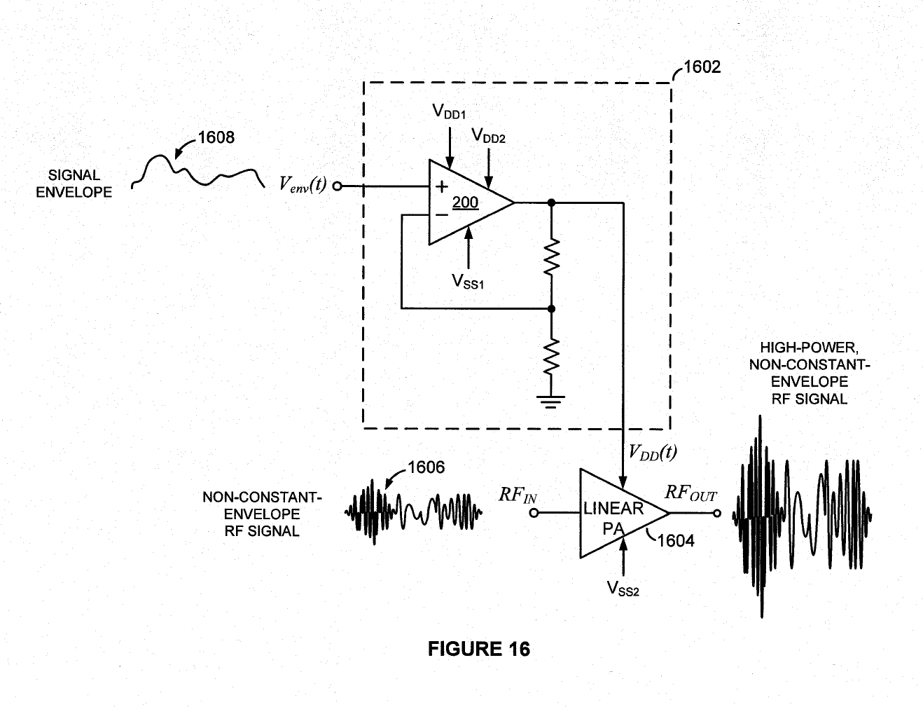

In addition to being well-suited for serving as a DPS for an SMPA in a polar modulator, the op amp 200 is also well-suited for serving as a DPS in an envelope (ET) tracking power amplifier. FIG. 16 illustrates how the op amp can be configured to serve as a DPS 1602 for an ET amplifier, which utilizes a linear PA 1604. Unlike an SMPA, which is switched between compressed and cutoff states, the linear PA 1604 is biased and configured to operate in its linear region of operation. A linear PA is not fully capable of performing drain modulation. Accordingly, the non-constant envelope signal 1606 must be applied to the RF input port of the linear PA 1604 (unlike in the polar modulator where the signal envelope 1310 is separated from the non-constant envelope signal 1312 and only the constant-envelop phase modulated RF 1314 is applied to the RF input port of the SMPA 1304). (Compare FIG. 16 to FIG. 13). Although the linear PA 1604 does not have the efficiency enhancement gained in a polar modulator by use of a SMPA, the efficiency of the linear PA 1604 can nevertheless be enhanced by employing the op amp 200 as a DPS 1602 for the linear PA 1604. The DPS 1602 produces a DPS voltage V_{DD}(t) that tracks the signal envelope 1608 of the non-constant envelope RF input signal 1606, thus preventing the linear PA 1604 from dissipating large amounts of power when the magnitude of the non-constant envelope RF input signal 1606 is small.

While various embodiments of the present invention have been presented, they have been presented by way of example and not limitation. It will be apparent to persons skilled in the relevant art that various changes in form and detail may be made to the exemplary embodiments without departing from the true spirit and scope of the invention. Accordingly, the scope of the invention should not be limited by the specifics of the exemplary embodiments of the invention but, instead, should be determined by the appended claims, including the full scope of equivalents to which such claims are entitled.

1-10. (canceled)

11. A gallium nitride based (GaN-based) operational amplifier (op amp), comprising:
a first GaN-based level-shifter; and
a first differential amplifier coupled to said first GaN-based level-shifter, said first differential amplifier including first and second GaN-based transistors.

12. The GaN-based op amp of claim 11, wherein the first and second GaN-based transistors of said first differential amplifier comprise first and second aluminum gallium nitride/gallium nitride (AlGaN/GaN) high electron mobility transistors (GaN-HEMTs).

13. The GaN-based op amp of claim 11, wherein said first GaN-based level-shifter is configured to ratiometrically establish a direct current operating point for said first differential amplifier.

14. The GaN-based op amp of claim 11, wherein said first GaN-based level-shifter comprises third and fourth GaN-based transistors.

15. The GaN-based op amp of claim 14, wherein said third and fourth GaN-based transistors are configured as first and second source followers.

16. The GaN-based op amp of claim 11, wherein said first differential amplifier includes a GaN-based tail current source.

17. The GaN-based op amp of claim 11, further comprising:
a second differential amplifier including third and fourth GaN-based transistors; and
a second gallium nitride based (GaN-based) level-shifter configured between said first differential amplifier and said second differential amplifier.

18. The GaN-based op amp of claim 17, further comprising an output stage including a fifth GaN-based transistor.

19. The GaN-based op amp of claim 18, wherein said output stage is configured as a source follower.

20. The GaN-based op amp of claim 18, wherein said second differential amplifier is single-endedly and directly coupled to said output stage.

21. An envelope following radio frequency power amplifier (RFPA) apparatus,
comprising:
a gallium nitride based (GaN-based) operational amplifier (op amp) configured to serve as a dynamic power supply (DPS); and
an RFPA configured to be powered by said DPS.

22. The envelope following RFPA apparatus of claim 21, wherein said RFPA comprises a switch-mode power amplifier.

23. The envelope following RFPA apparatus of claim 21, wherein said RFPA comprises a linear power amplifier.

24. The envelope following RFPA apparatus of claim 21, wherein said RFPA comprises a GaN-based RFPA.

25. The envelope following RFPA apparatus of claim 24, wherein said GaN-based op amp and said GaN-based RFPA are integrated in a single integrated circuit.
